(19) United States
(12) Patent Application Publication
(10) Pub. No.: US 2015/0219728 A1
(43) Pub. Date: Aug. 6, 2015

(54) METHOD AND DEVICE FOR MEASURING VARIOUS PARAMETERS OF MEMBRANE ELECTRODE ASSEMBLY IN FUEL CELL

(71) Applicant: Tsinghua University, Beijing (CN)

(72) Inventors: Pucheng PEI, Beijing (CN); Huachi XU, Beijing (CN); Hongshan ZHA, Beijing (CN)

(21) Appl. No.: 14/685,621

(22) Filed: Apr. 14, 2015

Related U.S. Application Data
(63) Continuation-in-part of application No. PCT/CN2013/083542, filed on Sep. 16, 2013.

(30) Foreign Application Priority Data
Nov. 6, 2012 (CN) 201210438967.9

(51) Int. Cl. G01R 31/36

(52) U.S. Cl. CPC G01R 31/3658; G01R 31/3648; G01R 31/3627

(57) ABSTRACT

A method and a device for measuring various parameters of a membrane electrode assembly (MEA) in a fuel cell. Hydrogen gas and nitrogen gas or air are supplied to the fuel cell to be tested. A voltage of the fuel cell is diminished by connecting to a load until the voltage is zero. The fuel cell is charged at a constant current. A constant current value is measured by a current sensor. A current signal and a voltage signal are collected by a data collector and are converted into digital quantity signals which are transmitted to a data processing unit. Data are automatically processed by programming of the data processing unit. Parameters, including an electrochemical active surface area of a catalyst, a double-layer capacitance, a hydrogen crossover current, and an impedance of the MEA of the fuel cell are acquired by differentiation and integral operations of the voltage data.

### CROSS-REFERENCE TO RELATED APPLICATIONS

This application is a continuation-in-part of International Patent Application No. PCT/CN2013/083542 with an international filing date of Sep. 16, 2013, designating the United States, now pending, and further claims priority benefits to Chinese Patent Application No. 201210438967.9 filed Nov. 6, 2012. The contents of all of the aforementioned applications, including any intervening amendments thereto, are incorporated herein by reference.

### BACKGROUND OF THE INVENTION

1. Field of the Invention

The invention relates to a method and a device for measuring various parameters of a membrane electrode assembly (MEA) in a fuel cell.

2. Description of the Related Art

Cyclic voltammetry (CV) is a common method for measuring an active area and a double-layer capacitance of a fuel cell. Such a method is only applicable for an individual fuel cell but not for a fuel cell stack. In addition, several times of CV scanning damages the fuel cell. Common methods for measuring hydrogen crossover current or an impedance of a MEA of the fuel cell often require a plurality of instruments thereby being time consuming.

### SUMMARY OF THE INVENTION

In view of the above-described problems, it is one objective of the invention to provide a method and a device for measuring various parameters of a MEA in a fuel cell stack that are adapted to acquire a plurality of parameters from one measurement.

To achieve the above objective, in accordance with one embodiment of the invention, there is provided a method for measuring various parameters of a MEA in a fuel cell. The method comprises the following steps:

1) filling two sides of a MEA of a fuel cell stack or an individual fuel cell to be tested with hydrogen gas and nitrogen gas, respectively, or with hydrogen gas and air, respectively; wherein, when the hydrogen gas and the nitrogen gas are filled, respectively, allowing the hydrogen gas and the nitrogen gas to pass through the fuel cell, or obstructing outlets of the hydrogen gas and the nitrogen gas; when the hydrogen gas and the air are filled, respectively, obstructing an outlet of an air side; connecting an external load to the fuel cell until an open-circuit voltage of the fuel cell is equivalent to zero;

2) charging the fuel cell to be tested at a constant current, continuously recording a voltage of each individual fuel cell, and stopping charging when the voltage of each individual fuel cell is not less than 0.5 V;

3) changing a constant current value twice or several times, repeating 2) whereby acquiring voltage data of each individual fuel cell under two or several constant currents;

4) differentiating a voltage change process of a certain individual fuel cell measured under two or several constant currents with respect to a time, determining voltage change rates dV/dt at a certain voltage of the individual fuel cell corresponding to two or several constant currents I_{G} charging processes;

5) linear fitting or computing based on the constant currents I_{G} and the voltage change rates dV/dt to obtain a current value corresponding to the voltage change rate of 0, and determining the current value corresponding to the voltage change rate of 0 as a hydrogen crossover current i_{H} of the MEA of the individual fuel cell;

6) charting a curve of (I_{G}−i_{H})/(dV/dt) in relation to the voltage V of the individual fuel cell, finding a lowest point L and a corresponding voltage V_{dl}; and determining a value of (I_{G}−i_{H})/(dV/dt) of the lowest point to be a double-layer capacitance C_{dl} of the MEA of the individual fuel cell;

7) performing integral

$${\int }_{0}^{{V}_{dl}} ( \frac{{I}_{G} - {i}_{H}}{d V / d t} - {C}_{dl} ) d v$$

on the curve of 6) whereby acquiring an electric charge Q_{Pt} corresponding to hydrogen desorption process on a catalyst; computing an electrochemical active surface area (EAS) of the catalyst of the MEA of the individual fuel cell by equation

$$EAS = \frac{{Q}_{Pt}}{q \cdot {W}_{Pt}}$$

where q represents a charge required to oxidize a monolayer of protons on platinum and W_{Pt} represents a platinum loading; or computing an effective area ratio R_{EA} of the catalyst by equation

$${R}_{EA} = \frac{{Q}_{Pt}}{q \cdot {A}_{MEA}}$$

for representing a ratio of the EAS of the catalyst to an effective area A_{MEA} of the MEA;

8) acquiring a voltage step change ΔV from an initial charging region, and computing an impedance R of the individual fuel cell using equation R=ΔV/I_{G}; and

9) repeating operations of 4)-8) on each individual fuel cell of the fuel cell stack whereby obtaining state parameters of the MEA of each individual fuel cell.

In a class of this embodiment, the hydrogen gas and the nitrogen gas or the air is humidified gas or non-humidified gas.

In accordance with another embodiment of the invention, there is provided with a device for measuring various parameters of a MEA in a fuel cell stack. The device comprises: a constant current power source, the constant current power source comprising a positive electrode and a negative electrode; a current sensor, the current sensor comprising a current signal port A; a data collector, the data collector comprising an analog input port B and a first data transmission port C; and a data processing unit, the data processing unit comprising a second data transmission port D. The positive electrode and the negative electrode of the constant current power source are connected to a cathode and an anode of a current collector plate of a fuel cell to be tested via conducting lines, respectively. The current sensor is disposed on the conducting line connecting the negative electrode of the constant current power source and the anode of the current collector plate of the fuel cell to be tested. The current signal port A of the current sensor is connected to the analog input port B of the data collector. The analog input port B of the data collector is connected to each individual fuel cell to be tested. The first data transmission port C of the data collector is connected to the second data transmission port D of the data processing unit. Collected voltage data of each individual fuel cell are performed with differentiation and integral operations by the data processing unit, and parameters, including the EAS of the catalyst, the double-layer capacitance, the hydrogen crossover current, and the impedance, of the MEA of the fuel cell to be tested are obtained.

The measured data are automatically processed by programming of the data processing unit.

The fuel cell to be tested is charged by the constant current power source at the constant current. The current during the charging is measured by the current sensor. The current signal of the current sensor and the voltage signal of each individual fuel cell of the fuel cell to be tested are collected by the data collector and are converted into digital quantity signals which are transported to the data processing unit.

The fuel cell to be tested is an individual fuel cell or a fuel cell stack. A number of voltage signal lines of the data collector corresponds with a number of the individual fuel cells.

Advantages according to embodiments of the invention are summarized as follows:

The measuring device is applicable for measurement of the fuel cell stack or the individual fuel cell. Four parameters including the hydrogen crossover current, the double-layer capacitance, the EAS of the catalyst, and the impedance of the fuel cell can be obtained from one measurement, thereby being advantageous in site operation, no damage, fast, and convenience.

The method and the device of the invention are used as the measuring method and device for studying and detecting consistency and lifetime of the MEA of each individual fuel cell of the fuel cell stack as well as used for diagnosing faults of the MEA of the fuel cell stack, such as leakage and deactivation of the catalyst.

### BRIEF DESCRIPTION OF THE DRAWINGS

The invention is described hereinbelow with reference to the accompanying drawings, in which:

FIG. 1 is a structure diagram of a device for measuring a fuel cell in accordance with one embodiment of the invention;

FIG. 2 is a chart showing voltage increase measured by the device of FIG. 1;

FIG. 3 is a chart showing differentiation of voltage during data processing in accordance with one embodiment of the invention;

FIG. 4 is a chart for calculating a hydrogen crossover current during data processing in accordance with one embodiment of the invention;

FIG. 5 is a curve of a differential capacitance during data processing; and

FIG. 6 is a chart for calculating an impedance of a fuel cell during data processing.

### DETAILED DESCRIPTION OF THE EMBODIMENTS

For further illustrating the invention, experiments detailing a method and a device for measuring various parameters of a MEA in a fuel cell are described below. It should be noted that the following examples are intended to describe and not to limit the invention.

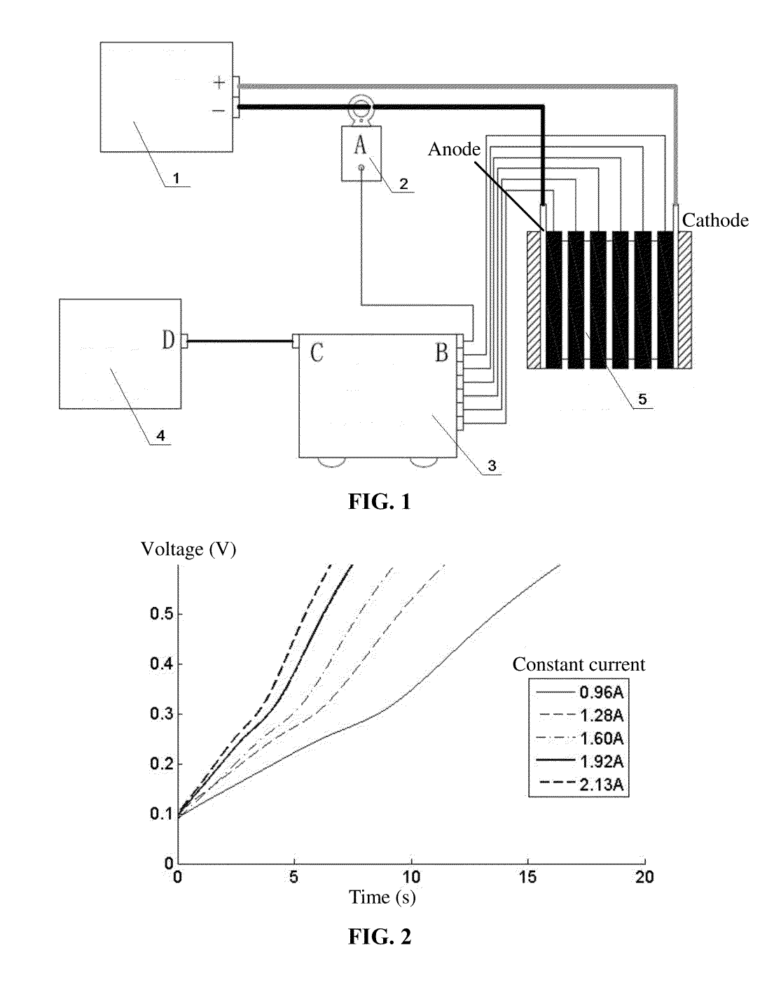

A structure diagram of a device measuring various parameters of a MEA in a fuel cell is illustrated in FIG. 1. The device comprises: a constant current power source 1, a current sensor 2, a data collector 3, and a data processing unit 4. A positive electrode and a negative electrode of the constant current power source 1 are connected to a cathode and an anode of a current collector plate of a fuel cell 5 to be tested via conducting lines, respectively. The current sensor 2 is disposed on the conducting line connecting the negative electrode of the constant current power source 1 and the anode of the current collector plate of the fuel cell 5 to be tested. A current signal port A of the current sensor 2 is connected to an analog input port B of the data collector 3. An analog input port B of the data collector 3 is connected to each fuel cell 5 to be tested. A first data transmission port C of the data collector 3 is connected to a second data transmission port D of the data processing unit 4.

Working principle of the measuring device illustrated in FIG. 1 is as follows: the fuel cell 5 to be tested is charged by the constant current power source 1 at a constant current which is measured by the current sensor 2. A current signal of the current sensor 2 and a voltage signal of each individual fuel cell 5 to be tested are collected and converted into a digital quantity signal by the data collector 3. The digital quantity signal is then transmitted to the data processing unit 4. Measured data are automatically processed by programming of the data processing unit 4. Differentiation and integral operations of voltage data of each individual fuel cell 5 to be tested are carried out, so that parameters, such as an electrochemical active surface area (EAS) of a catalyst, a double-layer capacitance, a hydrogen crossover current, and an impedance, of the MEA of the fuel cell 5 to be tested are obtained.

A method for measuring state parameters of a fuel cell 5 to be tested using the above measuring device is performed as follows:

(1) The anode and the cathode of the current collector plate of the fuel cell 5 to be tested are connected to the positive electrode and the negative electrode of the constant current power source 1, respectively. The data collector 3 is connected to each individual fuel cell 5 to be tested via signal lines.

(2) Hydrogen gas and nitrogen gas are filled in two sides of the MEA of the fuel cell 5 to be tested. Flow rates of the hydrogen gas and the nitrogen gas at the two side of each individual fuel cell are controlled at 0.6 L/min and 2 L/min, respectively; and both the hydrogen gas and the nitrogen gas are humidified gas at a temperature of 50° C.

(3) The fuel cell 5 to be tested is charged by the constant current power source 1 at a constant current of 0.96 A. The voltage of each individual fuel cell is continuously recorded, and the charging will not be sopped until the voltage of each individual fuel cell is no less than 0.6 V.

(4) The value of the constant current is changed to 1.28 A, 1.6 A, 1.92 A, and 2.13 A to repeat step (3), respectively, and measured data are acquired. Voltage changes of a designated individual fuel cell are collected together and represented in FIG. 2.

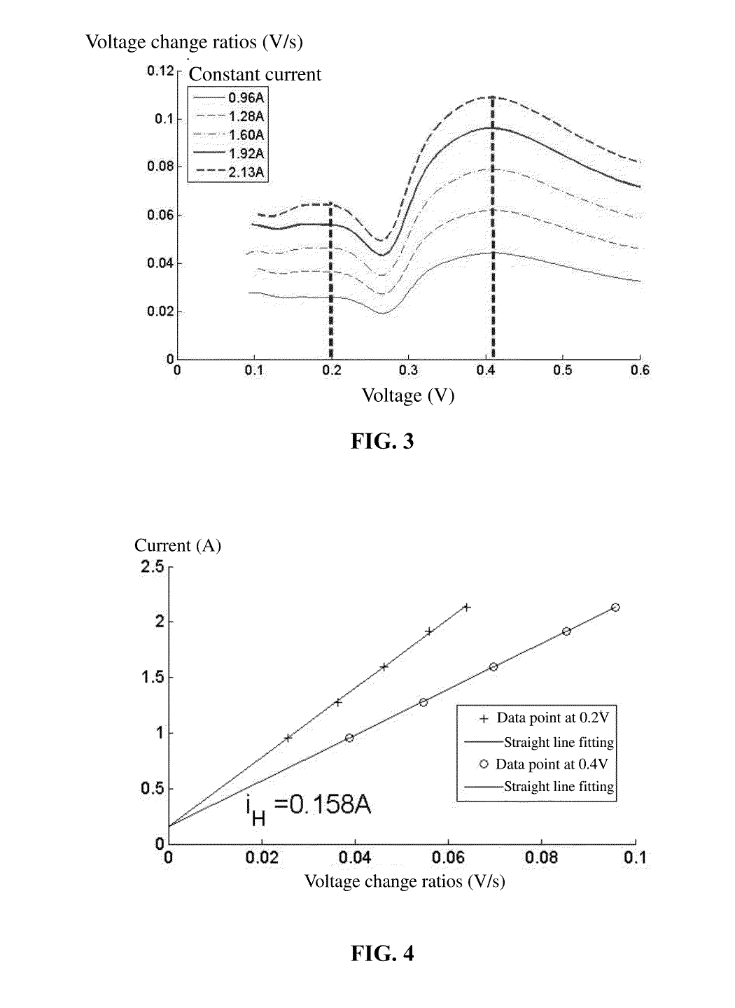

(5) The changing process of the voltage of each individual fuel cell measured under each constant current by the data processing unit 4 are differentiated with respect to a time, and results are illustrated in FIG. 3.

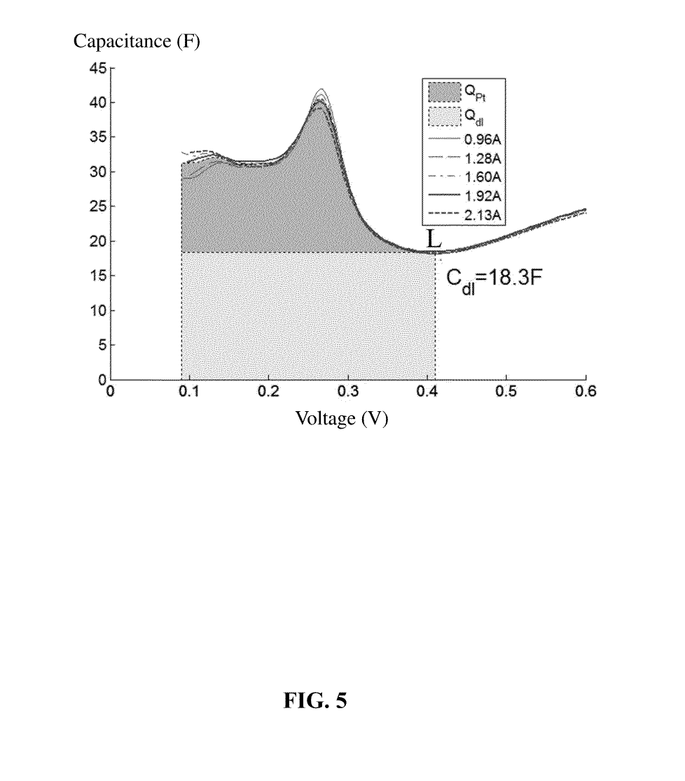

(6) Voltage change rates dV/dt of constant voltages of 0.4 V and 0.2 V of each individual fuel cell during the charging process corresponding to the above constant currents I_{G} are obtained from a differentiation chart of step (5), and linear fitting or computing is carried out to acquire a current value corresponding to a voltage change rate of 0, that is, a hydrogen crossover current (i_{H}=0.158 A) of the MEA of the individual fuel cell, as illustrated in FIG. 4.

(7) Data corresponding to a certain constant current are adopted to chart a curve of (I_{G}−i_{H})/(dV/dt) in relation to the voltage V of the individual fuel cell. A lowest point L and a corresponding voltage V_{dl} are found. A value of (I_{G}−i_{H})/(dV/dt) of such point is a double-layer capacitance (C_{dl}=18.3 F) of the MEA of the individual fuel cell. Data corresponding to other constant currents are treated by the same operation, and results are shown in FIG. 5.

(8) The curve in step (7) is performed with differentiation

$${\int }_{0}^{{V}_{dl}} ( \frac{{I}_{G} - {i}_{H}}{d V / d t} - {C}_{dl} ) d v$$

so as to acquire an electric charge (Q_{Pt}=3.4 C) corresponding to hydrogen desorption process of the catalyst. The EAS (EAS=32 m²/g) of the catalyst of the MEA of the individual fuel cell is obtained by equation of

$$EAS = \frac{{Q}_{Pt}}{q \cdot {W}_{Pt}}$$

where q represents a charge required to oxidize a monolayer of protons on platinum and W_{Pt} represents a platinum loading; or an effective area ratio (R_{EA}=110) which represents a ratio of the EAS of the catalyst to an effective area A_{MEA} of the MEA is calculated using equation

$${R}_{EA} = \frac{{Q}_{Pt}}{q \cdot {A}_{MEA}} .$$

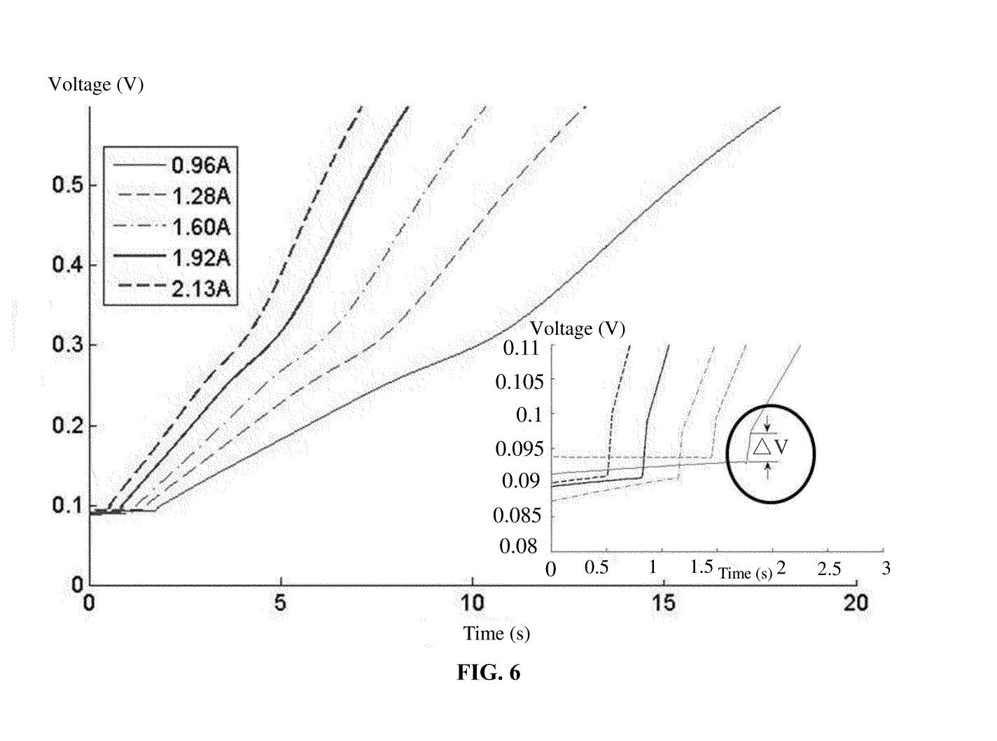

(9) As shown in FIG. 6, a voltage step change value ΔV is obtained from an initial charging region, and an impedance of the individual fuel cell (R=0.9 ω·cm²) is obtained using equation R=ΔV/I_{G}.

(10) Operations of steps (5)-(9) are conducted on each individual fuel cell of the fuel cell stack, and the state parameters of the MEA of each individual fuel cell of the fuel cell stack are acquired.

The fuel cell 5 to be tested is an individual fuel cell or a fuel cell stack. A number of voltage signal lines of the data collector 3 corresponds with a number of the individual fuel cells.

While particular embodiments of the invention have been shown and described, it will be obvious to those skilled in the art that changes and modifications may be made without departing from the invention in its broader aspects, and therefore, the aim in the appended claims is to cover all such changes and modifications as fall within the true spirit and scope of the invention.

The invention claimed is:

1. A method for measuring various parameters of a membrane electrode assembly (MEA) in a fuel cell, the method comprising:
1) filling two sides of a MEA of a fuel cell stack or an individual fuel cell to be tested with hydrogen gas and nitrogen gas, respectively, or with hydrogen gas and air, respectively; wherein, when the hydrogen gas and the nitrogen gas are filled, respectively, allowing the hydrogen gas and the nitrogen gas to pass through the fuel cell, or obstructing outlets of the hydrogen gas and the nitrogen gas; when the hydrogen and the air are filled, respectively, obstructing an outlet of an air side; connecting an external load to the fuel cell until an open-circuit voltage of the fuel cell is equivalent to zero;
2) charging the fuel cell to be tested at a constant current, continuously recording a voltage of each individual fuel cell, and stopping charging when the voltage of each individual fuel cell is not less than 0.5 V;
3) changing a constant current value twice or several times, repeating 2) whereby acquiring voltage data of each individual fuel cell under two or several constant currents;
4) differentiating a voltage change process of a certain individual fuel cell measured under two or several constant currents with respect to a time, determining voltage change rates dV/dt at a certain voltage of the individual fuel cell corresponding to two or several constant currents I_{G} charging processes;
5) linear fitting or computing based on the constant currents I_{G} and the voltage change rates dV/dt to obtain a current value corresponding to the voltage change rate of 0, and determining the current value corresponding to the voltage change rate of 0 as a hydrogen crossover current _{iH} of the MEA of the individual fuel cell;
6) charting a curve of (I_{G}−i_{H})/(dV/dt) in relation to the voltage V of the individual fuel cell, finding a lowest point L and a corresponding voltage V_{dl}; and determining a value of (I_{G}−i_{H})/(dV/dt) of the lowest point to be a double-layer capacitance C_{dl} of the MEA of the individual fuel cell;
7) performing integral
$${\int }_{0}^{{V}_{dl}} ( \frac{{I}_{G} - {i}_{H}}{d V / d t} - {C}_{dl} ) d V$$
on the curve of 6) whereby acquiring an electric charge Q_{Pt} corresponding to hydrogen desorption process on catalyst; computing an electrochemically active surface (EAS) of the catalyst of the MEA of the individual fuel cell by equation
$$EAS = \frac{{Q}_{Pt}}{q \cdot {W}_{Pt}}$$
where q represents a charge required to oxidize a monolayer of protons on platinum and W_{Pt} represents a platinum loading; or computing an effective area ratio R_{EA} of the catalyst by equation
$${R}_{EA} = \frac{{Q}_{Pt}}{q \cdot {A}_{MEA}}$$
for representing a ratio of the EAS of the catalyst to an effective area A_{MEA} of the MEA;
8) acquiring a voltage step change ΔV from an initial charging region, and computing an impedance R of the individual fuel cell using equation R=ΔV/I_{G}; and
9) repeating operations of 4)-8) on each individual fuel cell of the fuel cell stack whereby obtaining state parameters of the MEA of each individual fuel cell.

2. The method of claim 1, wherein the hydrogen gas and the nitrogen gas or the air is humidified gas or non-humidified gas.

3. A device for measuring various parameters of a MEA in a fuel cell stack according to the method of claim 1, the device comprising:
a) a constant current power source, the constant current power source comprising a positive electrode and a negative electrode;
b) a current sensor, the current sensor comprising a current signal port A;
c) a data collector, the data collector comprising an analog input port B and a first data transmission port C; and
d) a data processing unit, the data processing unit comprising a second data transmission port D;
wherein
the positive electrode and the negative electrode of the constant current power source are connected to a cathode and an anode of a current collector plate of a fuel cell to be tested via conducting lines, respectively;
the current sensor is disposed on the conducting line connecting the negative electrode of the constant current power source and the anode of the current collector plate of the fuel cell to be tested;
the current signal port A of the current sensor is connected to the analog input port B of the data collector;
the analog input port B of the data collector is connected to each individual fuel cell to be tested; and
the first data transmission port C of the data collector is connected to the second data transmission port D of the data processing unit.

4. The device of claim 3, wherein
the fuel cell to be tested is an individual fuel cell or a fuel cell stack; and
a number of voltage signal lines of the data collector correspond with a number of the individual fuel cells.
